(19) United States
(12) Patent Application Publication
(10) Pub. No.: US 2004/0113829 A1
(43) Pub. Date: Jun. 17, 2004

(54) Analog to digital conversion circuit

(76) Inventors: Hiroyuki Nakamoto, Kawasaki (JP); Kunihiko Gotoh, Tama (JP); Masato Yoshioka, Kawasaki (JP); Masahiro Kudo, Kawasaki (JP)

Correspondence Address: SWIDLER BERLIN SHEREFF FRIEDMAN, LLP, 3000 K STREET, NW, BOX IP, WASHINGTON, DC, 20007, US

(21) Appl. No.: 10/724,080

(22) Filed: Dec. 1, 2003

(30) Foreign Application Priority Data
Dec. 12, 2002 (JP) 2002-360826

(51) Int. Cl. H03M 1/36

(52) U.S. Cl. 341/159

(57) ABSTRACT

A comparison circuit that reduces the penetration current in the internal part of the comparison circuit is disclosed. The circuit also reduces the penetration current in the circuit that is connected to the next stage. The amplification circuit of the comparison circuit comprises an amplifier that outputs a digital signal after amplifying the input analog signal. The input analog signal that has a voltage that differs from the predetermined voltage in the 1^{st} time period and the predetermined voltage in the 2nd time period. A first switch stops the supply of electric power to the amplifier in the 1^{st} time period, and a second switch fixes the output of the said amplifier to the predetermined voltage in the 1^{st} time period.

### FIELD OF THE INVENTION

The present invention relates to an A/D converter (analog/digital converter) and more specifically, is related to an A/D converter that reduces the electric power that is consumed.

### BACKGROUND OF THE INVENTION

A prior art comparison circuit is shown in FIG. 1. This comparison circuit includes a comparator 12 with an auto zero and an inverter 11 that is used for A/D conversion. The comparator 12 with an auto zero comprises an inverter 14 that functions as an amplifier, a comparison switch 15, auto zero switches 16 and 17, as well as a capacitor 18. In the terminal on one side of the capacitor 18, going through the comparison switch 15 or the auto zero switch 16, the voltage Vi and the standard voltage Vr are supplied respectively. Here, the value of the capacitor 18 is represented by C.

FIG. 2 is a diagram showing the timing signal that controls the auto zero switches 16 and 17 and the comparison switch 15. The timing signal ø 0 that is shown in FIG. 2 is supplied to the auto zero switches 16 and 17. Further, the timing signal ø 1 is supplied to the comparison switch 15. In the auto zero time period, the timing signal ø 0 is HIGH and the auto zero switches 16 and 17 will be in an ON state (electrically connected state). At this time, the timing signal ø 1 will be LOW and the comparison switch 15 will be in an OFF state (disconnected state).

In the above-described manner, by switching on the auto zero switch 17, the input and the output of the inverter 14 will be short-circuited. Based on this, in the special characteristics of the input and the output of the inverter 14 of FIG. 3(a), the input/output voltage will be biased when the gain has the highest voltage. This voltage is usually set at about ½ of the voltage power source and is represented here as V_{TH}.

In this manner, the voltage of the terminal that is on the inverter 14 side in the capacitor 18, will now become V_{TH}. At this time, since the auto zero switch 16 will be in an ON state, the voltage of the terminal on the auto zero switch 16 side of the capacitor 18 will be Vr and the electric load that will build up in condenser 18 will be Q=C (Vr−V_{TH}).

In the next comparison time period, the timing signal ø 0 will be LOW and the auto zero switches 16 and 17 will be in an OFF state (disconnected state). At this time, the timing signal ø 1 will be HIGH and the comparison switch 15 will be in an ON state (electrically connected state). Since the comparison switch 15 will be electrically connected, the voltage of the terminal of the capacitor 18's comparison switch 15 side will change from Vr to Vi. At this time, the electric load of the capacitor 18 will not have a charging and discharging path and the electric load Q will be stored before or after the switch changes.

Consequently, in the capacitor 18 comparison switch 15-side terminal, when the change in voltage from Vi to Vr occurs, the same type of change on the voltage form Vi−Vr will occur in the terminal on the inverter 14. Since the charge in the inverter 14 terminal in the auto zero time period was V_{TH}, in the comparison time period it will be set to an voltage of Vi−Vr+V_{TH}.

If the gain of the inverter 11 and the inverter 14 are respectively set at A1 and A4, the output voltage of the comparison circuit Vo in the FIG. 1 is represented as Vo=A₄ A₁ (Vi−Vr+V_{TH}). In other words, at a time when the input relationship is Vi>Vr, the output Vo will be HIGH (>V_{TH}), and when the input relationship is Vi<Vr, the output Vo is LOW (<V_{TH}) and will operate as the comparator that decides the size relationship between the input Vi and Vr.

In the case of using a comparison circuit as mentioned above, during the auto zero time frame, the input output voltage of the inverter 14 will be biased by the highest voltage. At this time, as shown in the current flow characteristics of FIG. 3(b), the highest amount of penetrable current will flow through the inverter 14. Further, since the input of the inverter 11 will be V_{TH}, the penetrating current that flows in inverter 11 will also similarly be at a maximum. In this manner, when then current consumption of the comparison circuit gets large, it becomes the cause of the a noise generation and when the comparison circuit is used in an A/D conversion circuit, a problem wherein there is a reduction in the conversion precision, occurs.

In order to solve these kinds of problems, a method to reduce the penetration current in the inverters 11 and 14 has been suggested. FIG. 4 is a diagram showing one example of a comparison circuit that helps realize a reduction in the electric power for the inverter 11. In FIG. 4, the structural elements that are similar to FIG. 1 can be referenced with the same numbers.

In the comparison circuit shown in FIG. 4, a clocked inverter 11A replaces inverter 11. This is where it differs from the comparison circuit in FIG. 1. The clocked inverter 11A includes the PMOS transistor 21 and 22 and the NMOS transistor 23 and 24. The PMOS transistor 22 and the NMOS transistor 23 will get into an off state during the auto zero time frame and will function as the power supply switch.

This power source supply switch will get to a disconnected state during auto zero and based on this the penetration current flowing in the clocked inverter 11A will be reduced and, during the comparison period, by getting into an electrically connected state, it will behave in the same way as the normal inverters.

### SUMMARY OF THE INVENTION

Generally, the output of a comparison circuit used in an A/D conversion circuit is connected to the digital circuit of an encoder. The circuit structure shown in FIG. 4 aims to reduce the penetration current of the clocked inverter 11A, in order to turn off the power supply switch, the output voltage Vo of the clocked inverter will switch to a floating state. Consequently, the digital circuit that is connected at the next stage will have an input of floating voltage and there is a possibility that the penetration current may increase in the digital circuit at the next stage.

While taking the above into consideration, the present invention will not only decrease the penetration current in the inner part of the comparison circuit but also aims to offer a comparison circuit where it is possible to attain a reduction in the penetration current of the circuit that is connected in the following stage.

The amplification circuit of the present invention includes an amplifier that outputs a digital signal after amplifying the input analog signal. It has a voltage which differs from the predetermined voltage in the 1^{st} time period and the predetermined voltage in the 2nd time period. A first switch stops the supply of electric power to the amplifier in the 1^{st} time period and a second switch fixates the output of the amplifier to the predetermined voltage in the 1^{st} time period.

The comparison circuit of the present invention has a first and second voltage input. In the 1^{st} time period, the voltage that is at the middle level of predetermined upper and lower limits is output and, in the 2^{nd} time period, the comparator outputs a voltage that differs from the center level which represents the size relationship between the first and second voltage input. An amplifier then amplifies the output signal of the comparator and then outputs this as a digital signal. The first switch stops the supply of electric power to the amplifier in the 1^{st} time period and, the second switch stabilizes the output of the amplifier to the predetermined voltage in the 1^{St} time period.

In the above mentioned amplification circuit and comparison circuit, when the middle value is measured in the 1^{st} time period (auto zero time period) and when the analog signal has a value other than the middle value in the 2^{nd} time period (comparison time period) and converts this into a digital signal, the first switch is switched “OFF” in the auto zero time period and while the penetration current is lost, the 2^{nd} switch is put ON and the voltage output from the amplifier is fixed at the predetermined voltage level (grand or power source voltage). Based on this, the current consumed in the amplification circuit is reduced and it becomes possible to reduce the penetration current in the circuit that is connected in the next stage.

The A/D conversion circuit according to the present invention comprises of a plurality of comparison circuits that receive a substantially similar input voltage along with receiving different reference voltages. Also included is an encoder that encodes the digital signal output of the comparison circuit. Each one of the comparison circuits preferably outputs a middle level voltage that is between the predetermined upper and lower limits in the 1^{st} time period and we have a comparator that outputs an voltage that differs from the said middle level that indicates a size relationship between the input voltage and the corresponding reference charge in the 2^{nd} time period, an amplifier that amplifies the output signal from the comparator and then outputs this as a digital signal, the first switch stops the supply of electric power to the said amplifier in said 1^{st} time period, and second switch fixates the output of the said amplifier to the predetermined voltage in said 1^{st} time period.

The above-mentioned A/D conversion circuit encodes the multiple digital signals that indicate a size relationship between the input voltage and the reference voltage, that are respectively different. Since the amplification circuit according to the present invention is used, the penetration current in the comparison circuit is reduced and further, it is also possible to reduce the penetration current in the encoder that is connected in the next stage of the comparison circuit. Consequently, it is possible to avoid noise generation and a drop in the A/D conversion precision, caused by the amplification of the current consumed.

In the exemplary amplification circuit and comparison circuit, when the analog signal has an intermediate value during the auto zero time period, a value other than intermediate during the comparative period is converted to a digital signal by the amplifier. The voltage is set to a specified voltage when the 2nd switch is switched on, while the penetrating current is lost via the first switch being turned off during the auto zero time period. Thus, while reducing the current consumed by the amplification circuit, it can also reduce the penetrating current of the next connected circuit.

Further, the A/D conversion circuit encodes multiple digital signals that show the size relationship between the reference voltage and the input charge which are respectively different. It then outputs the digital code that shows the voltage level of the input charge. At this time, since the amplification circuit of the present invention is being used, the penetration current in the comparison circuit is reduced and it is also possible to reduce the penetration current in the encoder that is connected to the next stage of the comparison circuit. Consequently, it becomes possible to avoid noise generation and deterioration in the precision of A/D conversion caused by an increase in the current consumption.

### BRIEF DESCRIPTION OF THE DRAWINGS

FIG. 1 is a circuit diagram that shows an example of the construction of the prior art comparison circuit.

FIG. 2 is a timing diagram that shows an exemplary timing signal that controls the auto zero switch and the comparison switch shown in FIG. 1

FIG. 3(a) is a diagram indicating the input/output characteristics of the inverter shown in FIG. 1.

FIG. 3(b) is a diagram that shows exemplary current flow characteristics of the inverter shown in FIG. 1.

FIG. 4 is a circuit diagram showing a well-known example of a prior art comparison circuit that achieves the low electric power in the inverter.

FIG. 5 is a circuit diagram that shows an exemplary structure of the amplification circuit.

FIG. 6 is a timing diagram that shows an exemplary timing signal that controls the output control fixed switch and the timing signal that controls the power supply switch.

FIG. 7 is a diagram that shows a 1^{st} exemplary embodiment of the amplification circuit in FIG. 5.

FIG. 8 is a diagram that shows the 2^{nd} of the amplification circuit in FIG. 5.

FIG. 9 is a diagram that shows the configuration of a 1^{st} exemplary embodiment of the comparison circuit.

FIG. 10 is a diagram that shows the configuration of a 2^{nd} exemplary embodiment of the comparison circuit.

FIG. 11 is a diagram that shows the configuration of a 3^{rd} exemplary embodiment of the comparison circuit.

FIG. 12 is a diagram that shows one embodiment of the analog signal converter.

FIG. 13 is a diagram that shows the configuration of a 4^{th} exemplary embodiment of the comparison circuit.

FIG. 14 is a diagram that shows one example of the A/D conversion circuit according to the present invention.

### DETAILED DESCRIPTION OF THE PREFERRED EMBODIMENTS

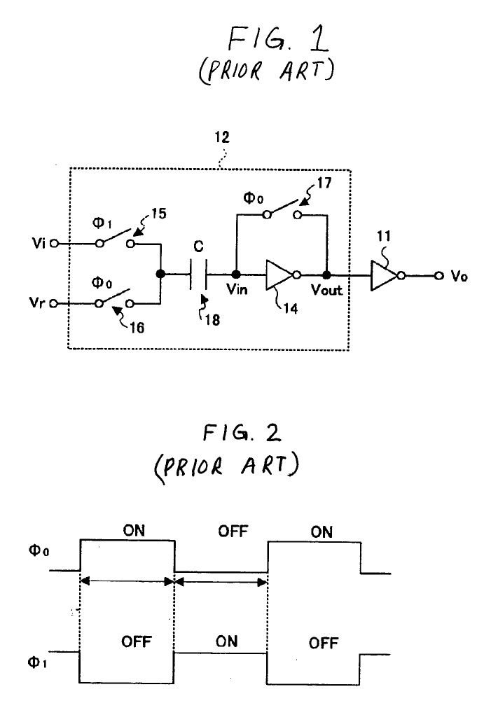

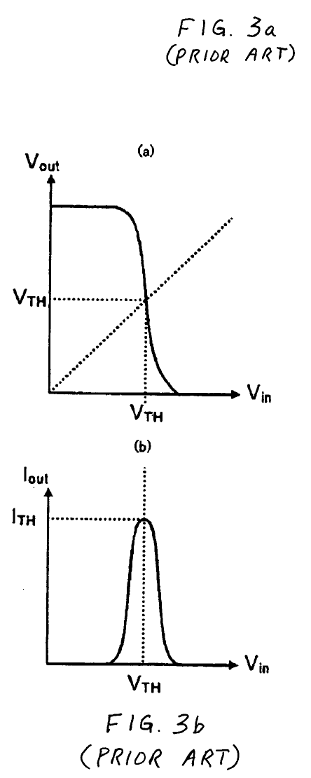

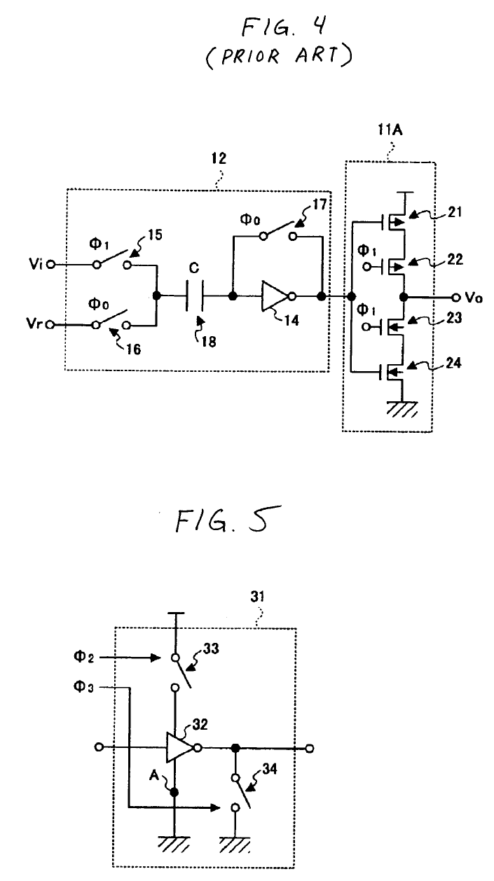

The amplification circuit 31 in the FIG. 5 embodiment is a device that is used instead of the inverter 11 meant for the A/D conversion in FIG. 1, and comprises an amplifier 32 that is used to convert the analog input into the digital output, a power supply switch 33, and an output signal fixed switch 34. For the amplifier 32, an inverter may be used, as shown in the example of FIG. 5. In one embodiment, the power supply switch 33 supplies power to the amplifier 32 with predetermined timing and the output signal fixed switch 34 sets the output from the amplifier 32 with predetermined timing to a predetermined voltage.

FIG. 6 is a diagram that shows the timing signal ø 3 which controls the output signal fixed switch 34 as well as the timing signal ø 2 which controls the power supply switch 33. As shown in FIG. 6, the timing signal ø 2 is substantially similar to the timing signal ø 1, which controls the comparison switch 15 of comparator 12 that has an attached auto zero, shown in FIG. 1, and ø 2 is LOW in the auto zero time period, and ø 2 is HIGH in the comparison time period. In other words, the power supply switch 33 is in an OFF state in the auto zero time period while it will be put ON in the comparison time period. Because of this, the amplifier 32 will be in an inoperative state in the auto zero time period and will be in an operative state in the comparison time period.

In one embodiment, the timing signal ø 3 is the same as the timing signal ø 0 that controls the auto zero switches 16 and 17 of the comparator 12 that has an attached auto zero component as shown in FIG. 1, and ø 3 is HIGH in the auto zero time period, and ø 3 is LOW in the comparison time period. In other words, the output signal fixed switch 34 is in an ON state in the auto zero time period while it will be put OFF in the comparison time period. Thus, the output of the amplifier 32 is preferably set to a predetermined voltage (grand voltage) in the auto zero time period, while in the comparison time period the amplifier 32 preferably attains the signal level to be output.

In one embodiment, the input to the amplification circuit 31 is a middle level analog signal in the auto zero time period, and will become an analog signal that indicates the size relationship between the input signal and the standard signal in the comparison time period. Since the amplifier 32 approaches the binary digital signal that indicates the analog signal has been input as either the HIGH or LOW values, the input analog signal is amplified and the wave is shaped accordingly. In the auto zero time period, the power supply switch 33 is turned OFF while the penetration current of the amplifier 32 is lost, and once the output signal fixed switch 34 is put ON, the output voltage from the amplifier 32 is set to the grand voltage. Based on this, the consumption of current in the amplification circuit 31 is reduced and it also becomes possible to reduce the penetration current in the circuit that is connected in the following stage.

Although the power supply switch 33 is positioned between the amplifier 32 and the power supply as shown in FIG. 5, it is acceptable to selectively position it between the grand, and the amplifier 32 represented as A. Further, as the output signal fixed switch 34 operatively connects the output signal of the amplifier 32 to the predetermined voltage in the auto zero time period, the voltage at the connection point is a grand voltage in the example of FIG. 5, but could also be a power source voltage instead.

When the analog signal has a value other than the middle value during the comparison time period, it takes the middle value during the auto zero time period and converts them into digital signals with the help of the amplifier. In the auto zero time period, the power supply switch is turned OFF and while the penetration current is lost, the output signal fixed switch is turned ON and the output voltage of the amplifier is set to grand. Based on this, the power consumption of the amplification circuit is reduced and it also becomes possible to reduce the penetration current in the circuit that is connected in the following stage.

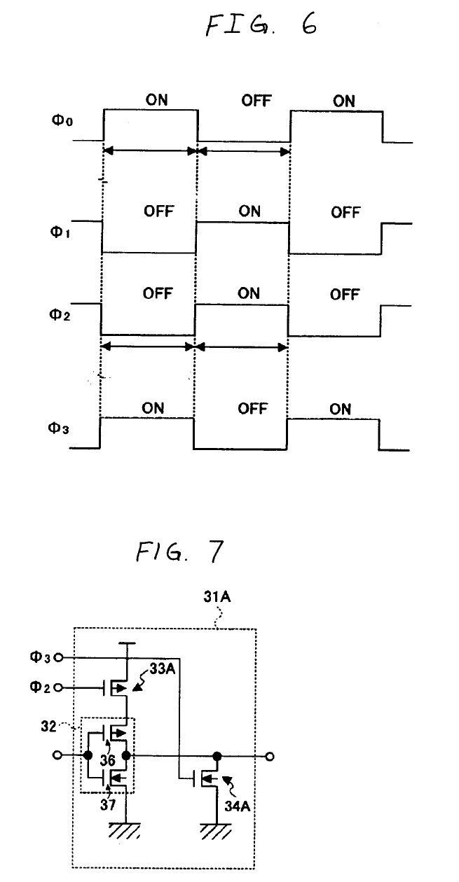

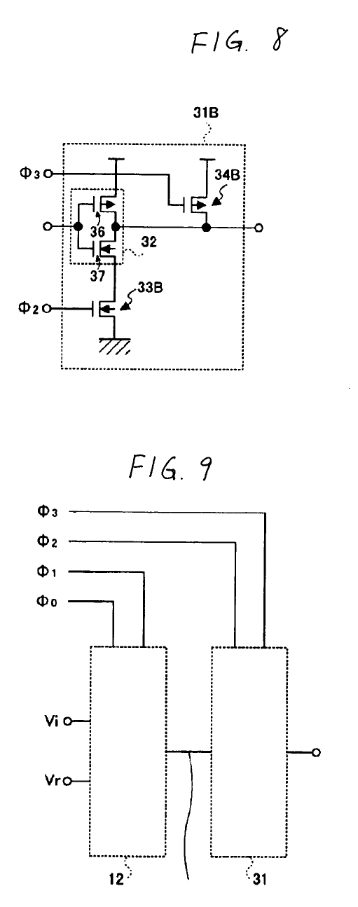

FIG. 7 is a diagram showing an exemplary embodiment of FIG. 5's amplification circuit. In FIG. 7, the amplification circuit 31A comprises an amplifier 32 that is used to convert the analog input into a digital output, a power supply switch 33A, and an output signal fixed switch 34A. The amplifier 32 is an inverter in the example of the FIG. 7, and comprises the PMOS transistor 36 and the NMOS transistor 37. The power supply switch 33A is preferably a PMOS transistor, and the output signal fixed switch 34A is preferably an NMOS transistor.

FIG. 8 is a diagram showing a second embodiment of the amplification circuit in FIG. 5. In FIG. 8, the amplification circuit 31B comprises an amplifier 32 that is used to convert the analog input into the digital output, a power supply switch 33B, and an output signal fixed switch 34B. In the FIG. 8 embodiment, the amplifier 32 is an inverter and comprises the PMOS transistor 36 and the NMOS transistor 37. The power supply switch 33B is preferably an NMOS transistor and may be selectively positioned between the amplifier 32 and the grand voltage. The output signal fixed switch 34B is preferably a PMOS transistor and may be selectively positioned where the output from the amplifier 32 is connected to the power source voltage.

In the two embodiments described above, not only can the current consumption in the amplification circuit be reduced, but it is also possible to reduce the penetration current in the circuit that is connected in the followings stage. Further, as will be explained below, when the channel width of the output signal fixed switch and the power supply switch is set to an appropriate width level, it is possible to attain a restriction in the drop in the operating speed.

In the FIG. 7 embodiment, the channel width of the power supply switch 33A is kept at twice or more the channel width of the PMOS transistor 36 included in amplifier 32. Further, the channel width of the output signal fixed switch 34A is almost the same or less than the channel width of the NMOS transistor 37. Further, in the embodiment shown in FIG. 8, the channel width of the power supply switch 33B is preferably kept at twice or more the level of the channel width of the NMOS transistor 37. Further, the channel width of the output signal fixed switch 34B is again kept at almost the same or a level lower than the channel width of the PMOS transistor 36.

By structuring it in the same fashion as described above, the reduction of the power supply to the load output by the increase in the ON resistance of the power supply witch 33A or 33B can be reduced as much as possible. Because of the decrease in the output load capacity from switches 34A and 34B, the reduction in the speed of change in the output signal may be reduced.

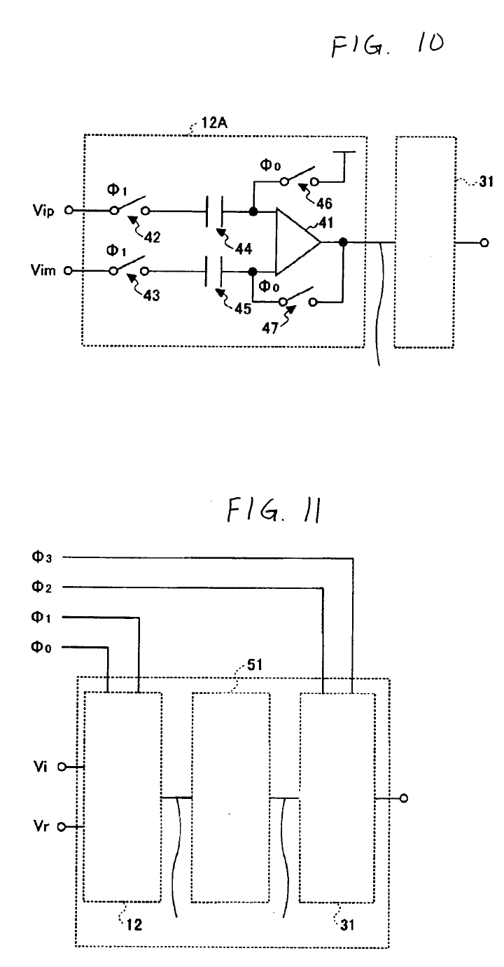

FIG. 9 is a diagram showing one embodiment of the comparison circuit according to the present invention. In FIG. 9, the structural elements that are similar to FIG. 1 and FIG. 5 are referenced using the same numbers.

The comparison circuit shown in FIG. 9 comprises an amplification circuit 31 and a comparator 12, which includes the auto zero function. The comparator 12, which includes the auto zero function, takes the input signal Vi and the standard signal Vr that is shown in FIG. 1 as the input, and outputs an analog signal at the middle level in the auto zero time period. In the comparison time period, an analog signal that represents the size relationship between the input signal Vi and the standard signal Vr is output. The amplification circuit 31 will turn OFF the power supply switch in the auto zero time period and will lose the penetration current, and the output signal fixed switch to be turned ON, and the output voltage from the amplifier may be set to grand. Based on this, not only is the current consumption in the amplification circuit be reduced, but the penetration current in the circuit that is connected to the next stage can also be reduced.

FIG. 10 is a diagram showing an exemplary comparison circuit. In FIG. 10, the structural elements that are the same as FIG. 9 are referenced using the same numbers and the explanation here is omitted. The comparison circuit shown in FIG. 10 comprises an amplification circuit 31 and comparator 12A, which includes the auto zero function. The comparator 12A, which includes the auto zero function, is a circuit that inputs the differential signal Vip and Vim. It preferably includes the differential amplifier 41, the 1^{st} differential input switch 42, the 2^{nd} differential input switch 43, the capacitors 44 and 45, and the auto zero switches 46 and 47. The auto zero switches 46 and 47 may be operatively connected to the auto zero time period after being controlled through the timing signal ø 0 shown in FIG. 2. The 1^{st} differential input switch 42 and the 2^{nd} differential input switch 43 may be connected to the comparison time period after being controlled by the timing signal ø 1 shown in FIG. 2.

FIG. 11 is a diagram showing another embodiment of the comparison circuit. In FIG. 11, the structural elements that are the same as FIG. 9 are referenced using the same numbers and the explanation here is omitted.

In one embodiment, the comparison circuit shown in FIG. 11 comprises the amplification circuit 31 and the comparator 12, which includes the auto zero function as well as the analog signal converter 51. The analog signal converter 51 may be a level shifter or an amplifier, and preferably outputs an analog signal after carrying out conversion of the analog signal input. In the stages after the comparator 12 that includes the auto zero switch, when the threshold of the multiple amplifiers that exist within the comparison circuit are different, the level shifter can be introduced. When the difference between the input signal and the standard signal is very minor, it is possible to introduce the amplifier in such a way that an accurate and speedy comparison result may be obtained. The analog signal converter 51 is a circuit that is introduced to achieve these kinds of objectives. However, in FIG. 11, there is no comparator 12 with an auto zero switch, thus there is a configuration where it is possible to set up the comparator 12A with the auto zero, as shown in FIG. 10.

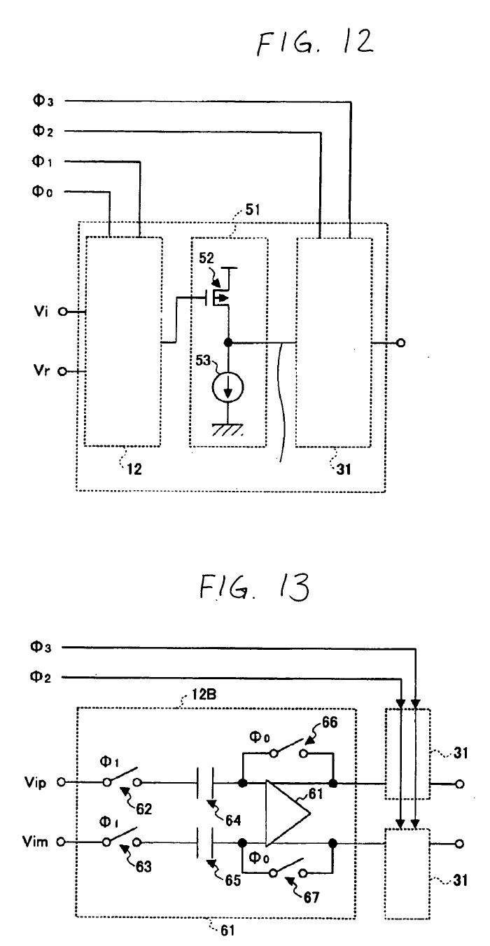

FIG. 12 is a diagram showing one embodiment of the analog signal converter 51. In FIG. 12, the structural elements that are the same as FIG. 9 are referenced using the same numbers and the explanation here is omitted.

The analog signal converter 51 shown in FIG. 12 is an amplifier and comprises a PMOS transistor 52 and the fixed source 53. Preferably, this amplifier can obtain quick and accurate comparison results even when the variation between the input signal and the standard signal is very small. The amplifier is introduced in order to amplify the signal.

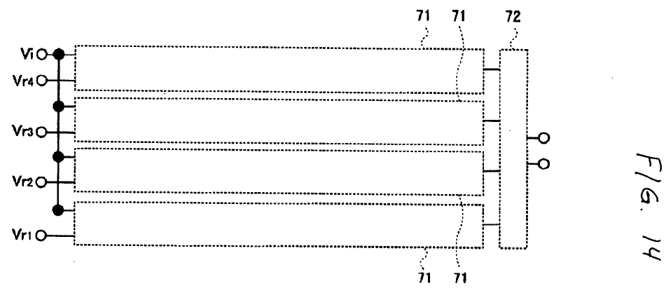

FIG. 13 is a diagram showing the configuration of one embodiment of the comparison circuit. In FIG. 13, the structural elements that are the same as FIG. 9 are referenced using the same numbers and the explanation here is omitted.

The comparison circuit in the FIG. 13 embodiment comprises the 2 amplification circuits 31 and the comparator 12B, which includes the auto zero function. The comparator 12B with the auto zero function preferably inputs the differential signal Vip and Vim, outputs the differential analog signal at the middle level during the auto zero time period, and during the comparison time period, it outputs the differential analog signal that shows the size relationship of the differential input signals. The comparator 12B with the auto zero function includes the differential amplifier 61, the first differential input switch 62, the 2^{nd} differential input switch 63, the capacitors 64 and 65, and the auto zero switches 66 and 67. The auto zero switches 66 and 67 may be operatively connected in the auto zero time period and are preferably controlled by the timing signal ø 0 shown in FIG. 2. The 1^{st} differential input switch 62 and the 2^{nd} differential input switch 63 may be operatively connected in the comparison time period and are controlled by the timing signal ø 1 that is shown in FIG. 2.

FIG. 14 is a diagram showing one embodiment of the structure of the A/D conversion circuit. The A/D conversion circuit in the FIG. 14 embodiment comprises a plurality of comparison circuits 71 and the encoder 72. The comparison circuit 71 has been shown in FIG. 9 or FIG. 11, and also includes the comparator with the auto zero function as well as the amplification circuit 31. The comparison circuit 71, when used alone, compares the input charge Vi which is the analog input signal and reference charge Vr, and outputs the charge level which indicates the size relationship between these two as a digital signal. In FIG. 14, four comparison circuits 71 have been set up and not only are the reference voltages that correspond to these circuits, Vr1, Vr2, Vr3, and Vr4 received, but the same input charge Vi is preferably also received. In one embodiment, each of the comparison circuits 71 compares the corresponding reference charges and the input charges Vi and outputs the digital signal that shows the size relationship between these two voltages.

In one embodiment, the digital signal output from comparison circuit 71 is preferably input in the encoder 72. The encoder 72 encodes the multiple digital signals that represent the size relationship between the reference voltages Vr1, Vr2, Vr3, and Vr4 as well as the input voltage Vi. It then outputs the digital code after indicating the charge level of the input voltage Vi.

In the A/D conversion circuit shown in the FIG. 14 embodiment, and in the portion of the amplification circuit of the comparison circuit 71, an amplification circuit of the present invention is employed. Thus, the penetration current in the comparison circuit 71 is reduced and it is also possible to reduce the penetration current in the encoder 72 that is connected to the next stage of the comparison circuit 71. Consequently, it becomes possible to avoid noise generation and deterioration in the precision of A/D conversion caused by an increase in the current consumption.

Although the present invention has been described with reference to particular embodiments, it will be understood to those skilled in the art that the invention is capable of a variety of alternative embodiments within the spirit of the appended claims.

1. An amplification circuit, comprising:
an amplifier, wherein said amplifier outputs a digital signal after amplifying an input analog signal, said analog signal having a voltage that differs from a predetermined voltage during a first time period and said digital signal having a voltage that fixates on said predetermined voltage during a second time period;
a first switch that stops the supply of electric power to said amplifier during said first time period; and
a second switch that fixates the output of said amplifier to the predetermined voltage in the first time period.

2. The amplification circuit according to claim 1, wherein said predetermined voltage is a voltage that is substantially in the center of an upper and lower limit, and wherein the voltage that differs from the predetermined voltage is substantially different than a voltage that is substantially in the center of an upper and lower limit.

3. The amplification circuit according to claim 1, wherein said amplifier is an inverter.

4. The amplification circuit according to claim 1, wherein said amplifier comprises a channel width, said width being more than two times the width of a channel width of a first switch, said first switch comprising a MOS transistor.

5. The amplification circuit according to claim 1, wherein said amplifier comprises a channel width, said width being less than the width of second switch, said second switch comprising a MOS transistor.

6. A comparison circuit, comprising:
a first and second voltage input, said first voltage having a value at the center of a predetermined upper and lower limit;
a comparator, wherein during a first time period a voltage at the center level of a predetermined upper and lower limits is output from said comparator, and wherein during a second time period a voltage that differs from said center level is output, said output during the second time period representative of a relationship between said first and second voltage input;
an amplifier that amplifies said output of said comparator and converts said amplified output to a digital signal;
a first switch that stops the supply of electric power to said amplifier during said first time period; and
a second switch that fixates the output of said amplifier to the predetermined voltage during said first time period.

7. The comparison circuit according to claim 6, comprising a pair of voltages that construct the differential signal between said first voltage and said second voltage.

8. The comparison circuit according to claim 6, wherein said amplifier receives an output signal from said comparator that has been converted by a signal conversion circuit, and wherein the signal conversion circuit converts the output signal of said comparator.

9. The comparison circuit according to claim 6, wherein said comparator comprises:
an inverter;
a switch that short circuits an input and an output from said inverter during a first time period, wherein a capacitor operatively connects the input of the said inverter to a first terminal;
a switch selectively positioned between a second terminal of said capacitor and said first voltage, wherein said switch is short circuited during said first time period; and
a switch selectively positioned between a second terminal of said capacitor and said second voltage, wherein said switch is short circuited during said second time period.

10. An analog to digital conversion circuit, comprising:
a plurality of comparison circuits operatively connectable to receive a plurality of different reference voltages, wherein each of said comparison circuits also receives the same input voltage;
an encoder that encodes a digital signal output from said comparison circuit, wherein each of the comparison circuits outputs a middle level of voltage in between an upper and a lower predetermined limit during a first time period, and wherein during a second time period the comparator outputs a voltage that differs from said middle level, said voltage during said second time period representing a relationship between the said input voltage and a corresponding reference charge;
an amplifier that amplifies the output signal of said comparator and then generates the output as a digital signal;
a first switch that stops the supply of electric power to said amplifier during said first time period; and
a second switch that fixates the output of said amplifier to a predetermined voltage during said first time period.
